(19) United States
(12) Patent Application Publication
(10) Pub. No.: US 2014/0362949 A1
(43) Pub. Date: Dec. 11, 2014

(54) REDUCED BANDWIDTH DIGITAL PREDISTORTION

(71) Applicant: Patrick Pratt, Mallow (IE)

(72) Inventor: Patrick Pratt, Mallow (IE)

(73) Assignee: ANALOG DEVICES TECHNOLOGY, Hamilton (BM)

(21) Appl. No.: 13/914,970

(22) Filed: Jun. 11, 2013

(51) Int. Cl. H03F 1/32; H04B 1/04

(52) U.S. Cl. CPC H03F 1/3241; H04B 1/0475
USPC 375/296

(57) ABSTRACT

A predetermined nonlinearity may be introduced between a digital predistorter and a power amplifier of a RF transmitter. The nonlinearity may be applied to an output of a digital predistorter. The application of the nonlinearity to the predistorter output may expand a bandwidth of the predistorter output from a first lower bandwidth to a higher second bandwidth of the power amplifier that may be needed to support a predetermined data transfer rate at the RF transmitter. Introducing this nonlinearity between the predistorter and the power amplifier may reduce the sampling rate and power requirements of components included as part of a predistortion device. As a result less noise may be generated and less power may be consumed, resulting in smaller, more efficient, and more accurate predistortion and/or RF transmission systems.

### BACKGROUND

Existing radio frequency (RF) transmitters often include a digital predistortion system that inversely models nonlinear characteristics of a radio power amplifier to improve the linearity of the amplifier and reduce distortion. These predistortion systems have allowed more power to be used from an existing amplifier without having to use a larger, more powerful and power consuming amplifier.

As the demand for faster and more efficient mobile communications devices continues to increase, the demand for RF transmitters supporting higher data transmission rates has also increased. In existing systems, these higher data transmission rates have been implemented by increasing the bandwidth of data signals transmitted by the RF transmitters. To support these wider bandwidths, the bandwidth of the digital predistortion system has also been increased.

This has resulted in higher sampling rates and bandwidth requirements for digital to analog converters that convert the digital inversely modeled power amplifier characteristics as applied to a digital signal to be transmitted from the digital domain to an analog domain before the converted signal is inputted to the analog power amplifier for transmission. The higher sampling rates and bandwidth requirements have increased the noise and the required power.

As demand for smaller, more efficient mobile devices continues to grow, there is a need for transmitters and predistortion systems that are able to support even wider bandwidths while producing less noise, consuming less power, and occupying less space.

### BRIEF DESCRIPTION OF THE DRAWINGS

FIG. 1 shows a first exemplary predistortion circuit in an embodiment.

FIG. 2 shows a second exemplary predistortion circuit in an embodiment.

FIG. 3 shows a third exemplary predistortion circuit in an embodiment.

FIG. 4 shows a fourth exemplary predistortion circuit in an embodiment.

FIG. 5 shows a fifth exemplary predistortion circuit in an embodiment.

FIG. 6 shows exemplary methods.

### DETAILED DESCRIPTION

A predetermined nonlinearity may be introduced at a digital predistorter or between the digital predistorter and a power amplifier of a RF transmitter. The nonlinearity may be applied to an output of the digital predistorter. The application of the nonlinearity to the predistorter output may expand a bandwidth of the predistorter output from a first lower bandwidth to a higher second bandwidth of the power amplifier that may be needed to support a predetermined data transfer rate at the RF transmitter.

Introducing this nonlinearity may enable the predistorter to operate at lower bandwidths than needed to support higher bandwidth at the power amplifier to support the predetermined data transfer rates. These lower operating bandwidths reduce the sampling rate and power requirements of components such as digital to analog converters included as part of a digital predistortion system. As a result less noise may be generated and less power may be consumed, resulting in smaller, more efficient, and more accurate predistortion and/or RF transmission systems.

In some instances, this nonlinearity may be created by factorizing an inverse modeled amplifier gain and/or phase characteristics wide band term into two or more narrow band terms. The nonlinearity may also include a memory component in which a past characteristic of the nonlinearity characteristic influences a present or future nonlinearity calculation. This memory component may increase the complexity of the modeled characteristics of the amplifier and/or the factorization of the modeled characteristics. These narrow band terms may be each applied separately to a digital input signal and then be converted to an analog domain before being mixed together to reconstitute the original wide band signal. The mixing may result in a nonlinear multiplication of the two or more narrow band terms. Factorizing a wide band amplifier characteristic term into two or more narrow band terms enables the inverse modeled predistortion to be applied separately and then converted to analog signals at each of the narrow bands. This may reduce the noise and power consumption as compared to performing these operations on the single wide band term. Once the narrow band terms have been converted to the analog domain, they may be mixed to form the wide band term inputted to the power amplifier.

To create the factorized narrow band terms, the inversely modeled amplifier gain and/or phase characteristics may be initially formulated in a factorized form instead of as a linear combination of past and current inputs and outputs. A nonlinear solver, such as a nonlinear least squares estimator may be used to estimate the coefficients of the factorized inversely modeled amplifier characteristics. In some instances, the factorization may include two narrow band terms, a first having one or more low order even terms and a second having one or more low order odd terms. In some instances the first narrow band term may include a first order and a third order distortion term and the second narrow band term may include a second order distortion term.

In other instances, the nonlinearity may be created by factorizing the inverse modeled amplifier gain and/or phase characteristics wide band term and then selecting only one lessor factor than the wide band term. The selected lessor factor may be applied to a digital input signal and the result may be converted from the digital domain to the analog domain. Since the selected factor is a lesser factor of the wide band term, the bandwidth associated with lesser factor will be inherently less than the bandwidth associated with the wide term. As a result, the noise generated and power consumed when applying the lesser factor to the digital input signal and converting the result to the analog domain may be less than that associated with the wide band term. The noise generated and power consumed may be further reduced by selecting a lower order factor.

Once a lesser factor has been selected, applied to the digital input signal, and then converted to the analog domain, a predetermined nonlinear analog function may be applied to the converted signal. The nonlinear analog function may be any nonlinear function that expands the bandwidth of the converted signal from that associated with the lesser selected factor to a predetermined bandwidth of the power amplifier supporting a predetermined data transfer rate. The nonlinear analog function may be selected on a case-by-case basis based on the characteristics of the amplifier, the bandwidth of the preamplifier, the bandwidth of the converted signal, and/or other factors affecting the transmission of data. In some instances the nonlinear analog function may be an exponential function that raises the converted signal to a predetermined power. In other instances the nonlinear analog function may include a quadratic, logarithmic, trigonometric, or other nonlinear function.

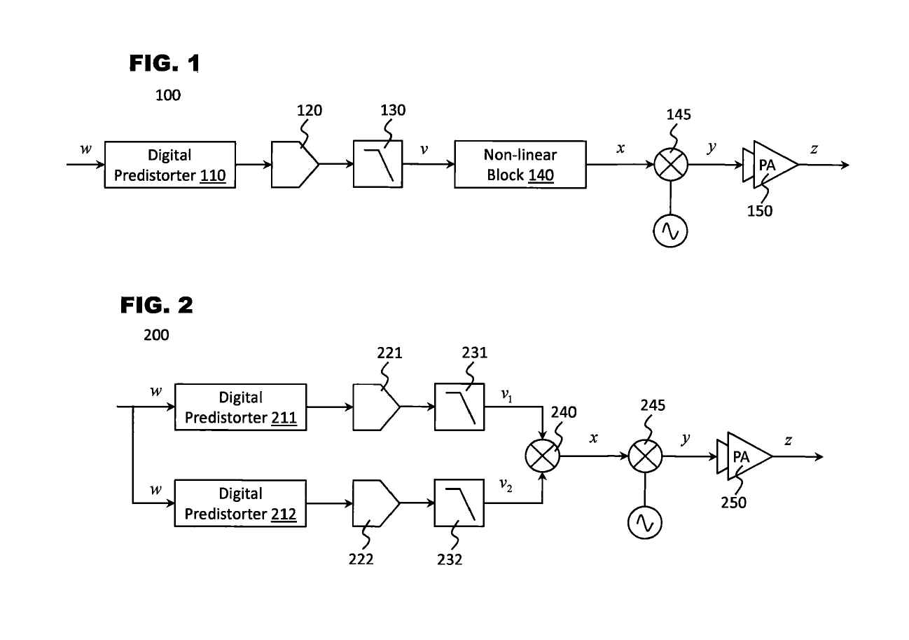

FIG. 1 shows a first exemplary predistortion device 100 in an embodiment. The predistortion device 100 may include a digital predistortion circuit 110 having circuitry introducing an inversely modeled gain and phase characteristic of a radio power amplifier 150. The radio power amplifier 150 may amplify outgoing analog signals to be transmitted wirelessly. The bandwidth of the outgoing analog signals inputted to the amplifier 150 for amplification may be a predetermined bandwidth that is selected to achieve a predetermined data transmission rate. In general, higher data transmission rates require wider bandwidth, so the predetermined bandwidth may increase in some instances proportionally to a desired data transmission rate.

The predistortion circuit 110 may be configured to operate at a lower bandwidth than the predetermined bandwidth associated with the amplifier 150. The predistortion circuit 110 may introduce the inversely modeled gain and phase characteristic of the amplifier 150 into a digital input signal at a lower bandwidth than the predetermined bandwidth of the amplifier 150. The digital input signal may be digitized version of an outgoing signal that is eventually transmitted at a RF transmitter. In some instances the amplifier 150 may be part of the predistortion device 100 but in other instances it may be an external component to the predistortion device 100 that is subsequently connected to it.

An digital to analog converter 120 may be coupled to the digital predistortion circuit 110 in the predistortion device 100. The digital to analog converter 120 may convert the digital signal outputted by the predistortion circuit 110 into an analog signal. Since the predistortion circuit 110 operates at a lower bandwidth than the predetermined bandwidth associated with the amplifier 150, the digital to analog converter 120 may be configured to only support this lower bandwidth instead the higher predetermined bandwidth associated with the amplifier 150. By reducing the supported bandwidth of the converter 120 to this lower bandwidth, less noise is generated and introduced into the converted analog signal by the converter 120. Additionally, less power is needed for the converter 120 to convert the lower bandwidth signal to the analog domain. Thus, more efficient and accurate predistortion devices 100 may be created.

A nonlinear analog circuit 140 may be coupled to the digital to analog converter 120. The nonlinear analog circuit may include circuitry configured to nonlinearly expand the analog converted output of the digital predistortion circuit 110 and the converter 120 from the lower bandwidth of digital predistortion circuit 110 to an intermediate bandwidth that may be less than the predetermined bandwidth associated with the power amplifier 150. The nonlinear circuit 140 may apply any nonlinear function, including but not limited to an exponential, logarithmic, or nonlinear polynomial function to the analog converted output of the digital predistortion circuit 110 to expand the analog converted output of the digital predistortion circuit 110 and converter 120 from the lower bandwidth to the predetermined bandwidth.

In some instances, the digital predistortion circuit 110 may be configured to introduce a third order intermodulation distortion term, which may in some instances also include a linear term, into the digital input signal. The analog nonlinear circuit 140 may be configured to nonlinearly expand the analog converted output of the digital predistortion circuit 110 and converter 120 to include a higher order intermodulation distortion term than the introduced third order term.

In other instances the digital predistortion circuit 110 may be configured to introduce other distortion terms, such as a second order intermodulation distortion term, into the digital input signal. However, in some instances, introducing these other distortion terms may have limited usefulness since these other distortion terms, such as second order distortion terms, may fall out of a particular band of interest once the output of the digital predistortion circuit 110 is expanded. The analog nonlinear circuit 140 may nonlinearly expand the analog converted output of the digital predistortion circuit 110 and converter 120 to a higher order intermodulation distortion term than the introduced second order term. Other higher order intermodulation distortion terms may be introduced by the predistortion circuit 110 into the digital input signal in different embodiments.

A frequency translation mixer 145 may be coupled between the analog nonlinear circuit 140 and the amplifier 150. The mixer 145 may translate the output of the analog nonlinear circuit 140 at the intermediate frequency to a radio frequency at which the amplifier 150 operates. The mixer 145 may mix the output of the nonlinear circuit 140 with an oscillating signal to perform the translation.

A low pass filter 130 may be coupled between the digital to analog converter 120 and the nonlinear analog circuit 140. The digital predistortion circuit 110, converter 120, and low pass filter 130 may covert a digital signal w to an analog signal having a bandwidth v which is less than the predetermined bandwidth y of the signal inputted to the power amplifier 150. The nonlinear circuit 140 may convert the signal from lower bandwidth v to an intermediate frequency x. Mixer 145 may translate the output of the nonlinear circuit 140 at intermediate frequency x to a radio frequency y at which the amplifier 150 is intended to be operated at. The power amplifier may amplify the signal from frequency bandwidth y to larger and more powerful output signal z for transmission.

In some instances, the predistortion device 100 may, but need not, include the radio power amplifier 150. The radio power amplifier 150 (whether part of the predistortion device 100 or separate from the predistortion device 100) may be coupled to an output of the nonlinear analog circuit 140. The radio power amplifier 150 may amplify the output of the nonlinear analog circuit so that it has sufficient power to be transmitted wirelessly. The amplifier may amplify predetermined bandwidth expanded analog converted output of the digital predistortion circuit 110.

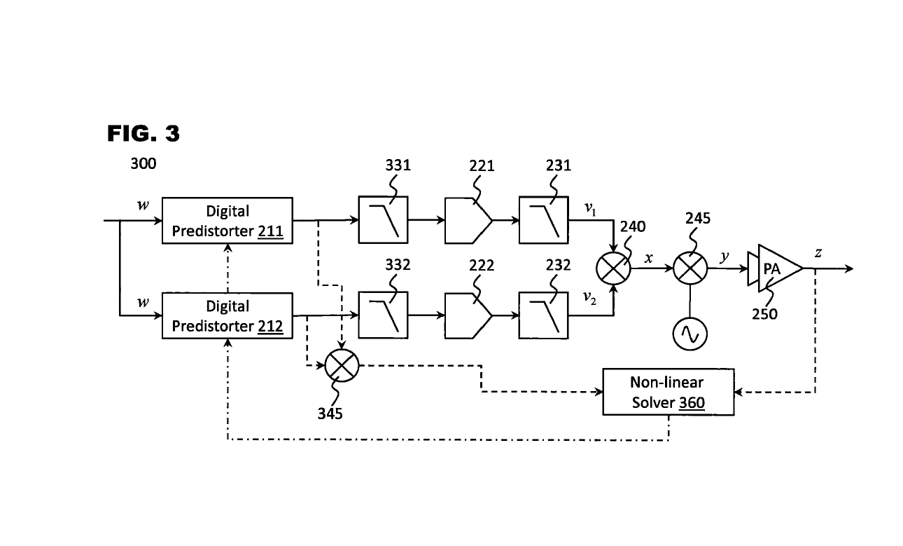

FIG. 2 shows a second exemplary predistortion device 200 in an embodiment. Although this predistortion device 200 is depicted as only including two predistortion circuits 211 and 212, two digital to analog converters 221 and 222, and two low pass filters 231 and 232, in different embodiments, different numbers of predistortion circuits 211 and 212, converters 221 and 222, and filters 231 and 232 may be included.

Predistortion device 200 may include two or more digital predistortion circuits 211 and 212. Each of the digital predistortion circuits 211 and 212 may be coupled in a parallel to a source of a digital input signal w to be transmitted at a RF transmitter. Each of the predistortion circuits 211 and 212 may introduce an inversely modeled gain and phase characteristic of a radio power amplifier 250 amplifying analog signals to be transmitted at the RF transmitter. The amplifier 250 may amplify signals at a predetermined bandwidth x selected to correspond to a particular data transmission rate. Each of the predistortion circuits 211 and 212 may be configured to operate at a lower bandwidth v₁ and v₂ than the predetermined bandwidth x associated with the amplifier 250. Each of the predistortion circuits 211 and 212 may introduce an inversely modeled gain and phase characteristic of a radio power amplifier 250 into the digital input signal at their respective lower bandwidths v₁ and v₂.

Predistortion device 200 may include two or more digital to analog converters 221 and 222. Each converter 221 and 22 may be coupled to a respective digital predistortion circuit 211 and 212.

Predistortion device 200 may include an analog mixer 240 coupled to each of the digital to analog converters 221 and 222. The mixer 240 may mix the analog converted outputs of each of the lower bandwidth digital predistortion circuits 211 and 212 to generate a signal having the predetermined bandwidth associated with the amplifier 250. Each of the lower bandwidths v₁ and v₂ may be selected to generate the intermediate bandwidth x when mixed at the analog mixer 240. In some instances, the analog mixer 240 may be an analog multiplier that multiplies the analog converted outputs of each of the lower bandwidth digital predistortion circuits 211 and 212 together.

A frequency translation mixer 245 may be coupled between the analog mixer 240 and the amplifier 250. The frequency translation mixer 245 may translate the output of the analog mixer 240 at the intermediate frequency x to a radio frequency y at which the amplifier 250 operates. The frequency translation mixer 245 may mix the output of the analog mixer 240 with an oscillating signal to perform the translation.

The two or more digital predistortion circuits may include a first predistortion circuit 211 introducing a linear and third order intermodulation distortion term into the digital input signal w and a second predistortion circuit 212 introducing a second order intermodulation distortion term into the digital input signal w. The analog mixer 240 may multiply the analog converted outputs of the first and the second predistortion circuits 211 and 212. The mixer 240 may also generate from the multiplication signal x including a fifth order intermodulation distortion term.

In some instances, the analog mixer 240 may be linear, in that none of the mixer inputs in the signal chain may be intermixed or intermodulated, but in other instances some intermixing or intermodulation of the signals may be occur. This mixer signal intermixing or intermodulation nonlinearity may be incorporated into an overall transmitter nonlinearity. The mixer nonlinearity may also be modeled and removed by virtue of the predistortion introduced by the predisortion device 200. Indeed, in some instances, mixer nonlinearities may be advantageous when they widen the signal bandwidth of the intermediate signal x so that the lower bandwidths v₁ and v₂ can be narrowed. In some instance, it may be desirable to intentionally add a nonlinear multiplying operation at mixer 240.

Predistortion device 200 may also include a first digital to analog converter 221 coupled to the first predistortion circuit 211 and the analog mixer 240. Predistortion device 200 may also include a second digital to analog converter 222 coupled to the second predistortion circuit 212 and the analog mixer 240. In some instances predistortion device 200 may also include the radio power amplifier 250, but in other instances the amplifier may be an external component to the predistortion device 200 that may be subsequently connected to it. Predistortion device 200 may also include a first and a second low pass filter 231 and 232 coupled between the respective first and second digital to analog converters 221 and 222 and the analog mixer 240.

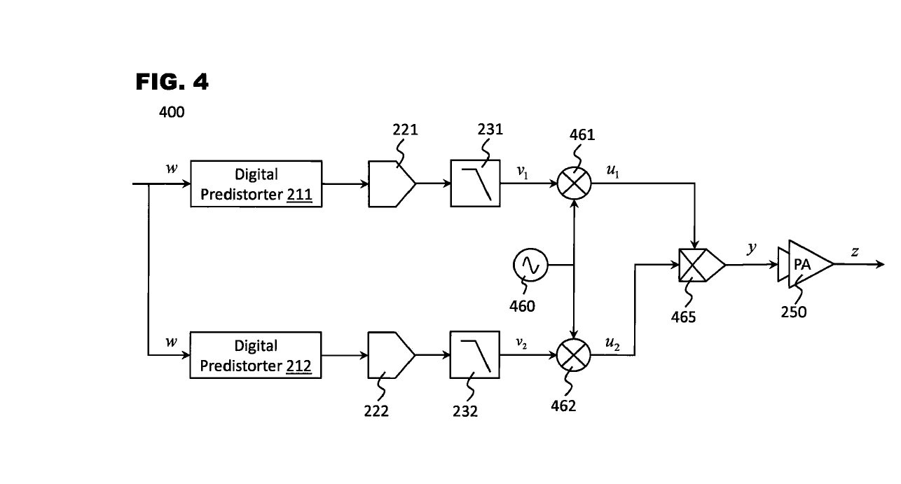

FIG. 3 shows a third exemplary predistortion device 300 in an embodiment. The third exemplary predistortion device 300 includes each of the components and functionality of the components of the predistortion device 200 in FIG. 2 with the additional components of a digital mixer 345, nonlinear solver 360, and filters 331 and 332.

The digital mixer 345 may be a digital multiplier coupled to the first and the second predistortion circuits 211 and 212. The digital mixer 345 may multiply an output of the first predistortion circuit 211 by an output of the second predistortion circuit 212.

The nonlinear solver 360 may be a nonlinear least squares solver coupled to the first and the second predistortion circuits 211 and 212, the digital multiplier 345, and an output of the power amplifier 250. The nonlinear least square solver 360 may include circuitry configured to perform a nonlinear least squares analysis of an output of the digital multiplier 345 and an output of the power amplifier 250. The nonlinear least square solver 360 may also include circuitry configured to calculate coefficient vectors of the second order and the third order intermodulation distortion terms from the nonlinear least squares analysis. The nonlinear least square solver 360 may also include circuitry configured to provide the first and the second predistortion circuits 211 and 212 with filter coefficient updates from the calculated coefficient vectors.

The nonlinear least square solver 360 may be configured to evaluate the output of digital multiplier 345 as a function of a product of the second order and the third order intermodulation distortion terms. In some instances, the nonlinear least square solver 360 may be configured to perform the nonlinear least squares analysis using a Levenberg-Marquardt algorithm as shown in equation (1) below, but other algorithms may be used in different instances.

$${[ \begin{matrix}{\hat{G}}_{3} \\ {\hat{F}}_{2}\end{matrix} ]}_{k} = {[ \begin{matrix}{\hat{G}}_{3} \\ {\hat{F}}_{2}\end{matrix} ]}_{k - 1} + {( {J}^{H} J + λ I )}^{- 1} ( x - \hat{x} ) \qquad ( 1 )$$

In equation (1), G and F are coefficient vectors of the third order and second order intermodulation distortion terms estimated according to the nonlinear least squares analysis, k is a current iteration, k−1 is a previous iteration, J is the Jacobian matrix, J^{H} is the conjugate transpose of the Jacobian matrix, I is the identity matrix, λ is a predetermined scaling factor, x is an actual power amplifier input signal, 2 is an estimated power amplifier input signal. The Jacobian matrix J is shown in equation (2) below.

J=[Y₃x₂ Y₂x₃] (2)

In equation (2), Y is a matrix of respective third and second order intermodulation distortion terms from the current and past output signals of the power amplifier and x is a vector of second and third order intermodulation distortion terms in a power amplifier input signal.

The predistortion device 300 may include two or more low pass filters, such as low pass filters 331 and 332. Each of the low pass filters 331 and 322 may be coupled between a respective predistortion circuit 211 and 212 and a respective digital to analog converter 221 and 222. Each of these filters 331 and 332 may band limit the inverse modeling at each of the respective predistortion circuits 211 and 212 based on a setting of the respective low pass filter 331 and 332.

The nonlinear least square solver 360 may in some instances model a fifth order intermodulation distortion as a product of third order and second order intermodulation distortion terms as shown in equation (3) below.

x₅=x₂x₃=(1+Y₂F₂)·(Y₃G₃) (3)

In equation (3), Y is a matrix of respective second and third order intermodulation distortion terms from the current and past output signals of the power amplifier, F and G are coefficient vector estimates of the respective second order and third order intermodulation distortion terms, and x is a vector of respective fifth order, second order, and third order intermodulation distortion terms in a power amplifier input signal.

FIG. 4 shows a fourth exemplary predistortion device 400 that is a variation of the second predistortion device 200 shown in FIG. 2.

Predistortion device 400 may include two or more digital predistortion circuits 211 and 212. Each of the digital predistortion circuits 211 and 212 may be coupled in a parallel to a source of a digital input signal w to be transmitted at a RF transmitter. Each of the predistortion circuits 211 and 212 may introduce an inversely modeled gain and phase characteristic of a radio power amplifier 250 amplifying analog signals to be transmitted at the RF transmitter. The amplifier 250 may amplify signals at a predetermined radio frequency bandwidth y selected to correspond to a particular data transmission rate. Each of the predistortion circuits 211 and 212 may be configured to operate at a lower bandwidth v₁ and v₂ than the predetermined bandwidth y associated with the amplifier 250. Each of the predistortion circuits 211 and 212 may introduce an inversely modeled gain and phase characteristic of a radio power amplifier 250 into the digital input signal at their respective lower bandwidths v₁ and v₂.

Predistortion device 400 may include two or more digital to analog converters 221 and 222. Each converter 221 and 22 may be coupled to a respective digital predistortion circuit 211 and 212.

Predistortion device 400 may also include two or more analog mixers 461 and 462. Each of these mixers 461 and 462 may be coupled to a respective digital to analog converter 221 and 222 and one or more oscillating signal sources 460. The oscillating signals of sources 460 may be selected to generate respective signals having the predetermined intermediate bandwidths u₁ and u₂ that are higher than bandwidths v₁ and v₂ but lower than the predetermined bandwidth y associated with the amplifier 250. The outputs of analog mixers 461 and 462 may be coupled to a multiplier 465 that may multiply signals from the mixers 461 and 462 together thereby obtaining a multiplied signal at the predetermined bandwidth y associated with the amplifier 250 from the signals at intermediate bandwidths u₁ and u₂.

Predistortion device 400 may also include a radio power amplifier 250. At least one of the digital predistortion circuits, the digital to analog converters, and the analog mixers (in this example predistortion circuit 212, converter 222, and mixer 562) may be coupled to a signal input of the radio power amplifier 250. Additionally, at least one the digital predistortion circuits, the digital to analog converters, and the analog mixers (in this example predistortion circuit 211, converted 221, and mixer 561) may be coupled to a supply input of the radio power amplifier 250.

The predistortion device 400 may also include two or more low pass filters 231 and 232. Each of these filters 231 and 232 may be coupled between each respective digital to analog converter 221 and 222 and each respective analog mixer 461 and 462.

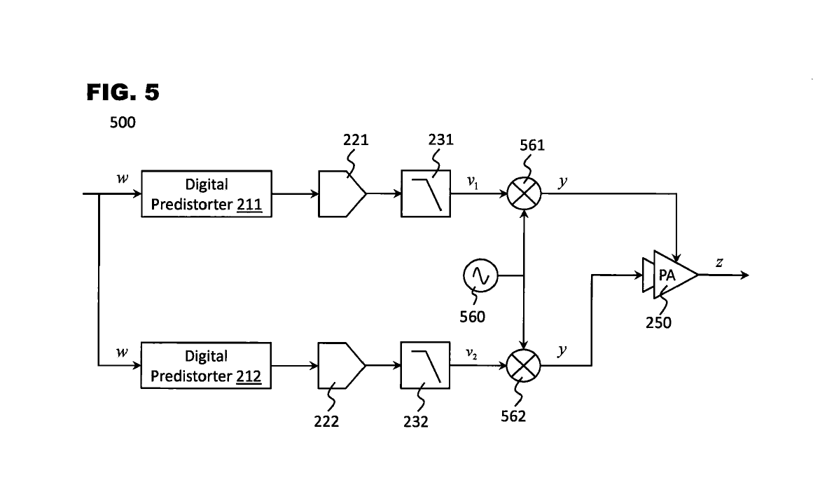

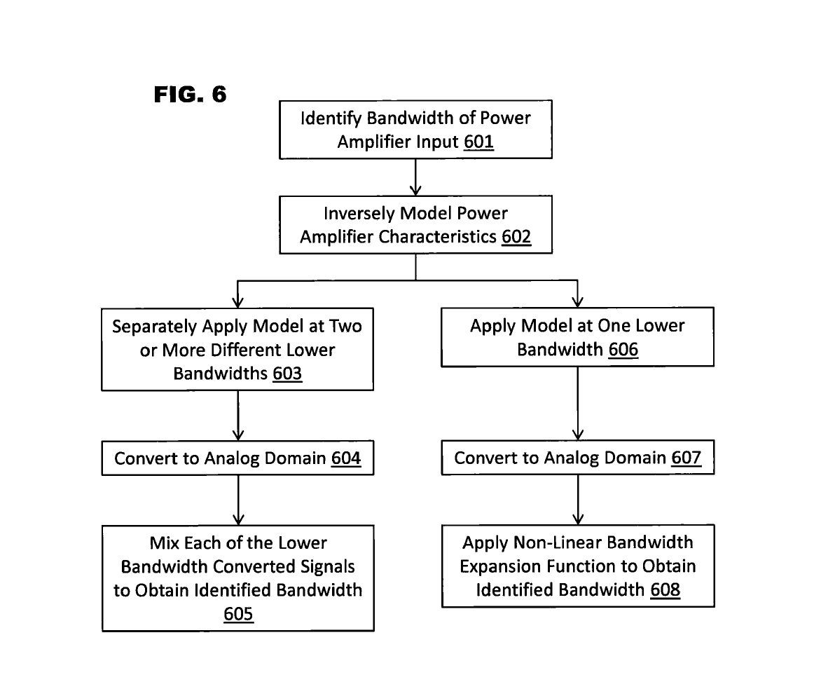

FIG. 5 shows a fifth exemplary predistortion device 500 that is also a variation of the second predistortion device 200 shown in FIG. 2.

Predistortion device 500 may include two or more digital predistortion circuits 211 and 212. Each of the digital predistortion circuits 211 and 212 may be coupled in a parallel to a source of a digital input signal w to be transmitted at a RF transmitter. Each of the predistortion circuits 211 and 212 may introduce an inversely modeled gain and phase characteristic of a radio power amplifier 250 amplifying analog signals to be transmitted at the RF transmitter. The amplifier 250 may amplify signals at a predetermined bandwidth x selected to correspond to a particular data transmission rate. Each of the predistortion circuits 211 and 212 may be configured to operate at a lower bandwidth v₁ and v₂ than the predetermined bandwidth y associated with the amplifier 250. Each of the predistortion circuits 211 and 212 may introduce an inversely modeled gain and phase characteristic of a radio power amplifier 250 into the digital input signal at their respective lower bandwidths v₁ and v₂.

Predistortion device 500 may include two or more digital to analog converters 221 and 222. Each converter 221 and 22 may be coupled to a respective digital predistortion circuit 211 and 212.

Predistortion device 500 may also include two or more analog mixers 561 and 562. Each of these mixers 561 and 562 may be coupled to a respective digital to analog converter 221 and 222 and one or more oscillating signal sources 560. The oscillating signals of sources 560 may be selected to generate respective signals having the predetermined bandwidth y when mixed with a respective signal at a respective one of the lower bandwidths v₁ and v₂ outputted at the respective digital to analog converter 221 and 222.

Predistortion device 500 may also include a radio power amplifier 250. At least one of the digital predistortion circuits, the digital to analog converters, and the analog mixers (in this example predistortion circuit 212, converter 222, and mixer 562) may be coupled to a signal input of the radio power amplifier 250. Additionally, at least one the digital predistortion circuits, the digital to analog converters, and the analog mixers (in this example predistortion circuit 211, converted 221, and mixer 561) may be coupled to a supply input of the radio power amplifier 250.

The predistortion device 500 may also include two or more low pass filters 231 and 232. Each of these filters 231 and 232 may be coupled between each respective digital to analog converter 221 and 222 and each respective analog mixer 561 and 562.

As shown in FIGS. 4 and 5, the multiplication of the lower bandwidth signals may occur after mixing at mixers 461, 462, 561, and/or 562, such as at intermediate bandwidths u₁ and u₂ or in the radio frequency domain at the predetermined bandwidth y. The multiplication may be performed by a multiplier such as real multiplier 465 (instead of a complex multiplier such as multiplier 240 in FIG. 2) or by modulating the power supply of amplifier 250.

FIG. 6 shows exemplary methods. In box 601, a bandwidth of an input to a radio power amplifier may be identified.

In box 602, a gain characteristic and a phase characteristic of the radio power amplifier may be inversely modeled in a digital domain at one or more lower bandwidths than the identified bandwidth associated with the power amplifier in box 601.

In box 603, the inversely modeled digital gain and phase characteristics may be separately applied to the digital input signal at each of two or more lower bandwidths. In box 606, the inversely modeled digital gain and phase characteristics may be applied to the digital input signal at only one lower bandwidth, instead of at two or more lower bandwidths in box 603.

In box 604, the separately applied modeled gain and phase characteristics in box 603 may be converted to respective analog signals. In box 607, the modeled gain and phase characteristics applied at the only one lower bandwidth in box 606 may be converted to an analog signal.

In box 605, each of the lower bandwidth signals converted in box 604 may be mixed together to form a mixed signal having the higher bandwidth identified in box 601. In box 608, a nonlinear function may be applied to the analog signal converted in box 607. The nonlinear function may expand the analog signal converted in box 607 from the lower bandwidth to the higher bandwidth identified in box 601. The nonlinear function may be an exponential, logarithmic, or nonlinear polynomial function increasing an order of an intermodulation distortion term modeled at the lower bandwidth.

In some instances, the digital gain and phase characteristics may be inversely modeled at two different lower bandwidths. A first of these lower bandwidths may introduce a linear and a third order intermodulation distortion term into the digital input signal. A second of these lower bandwidths may introduce a second order intermodulation distortion term into the digital input signal. Once these intermodulation distortion terms have been converted to the analog domain, the converted linear and third order analog terms may be multiplied by the converted second order analog term to mix the first and the second bandwidth signals together. This mixed signal may include a fifth order intermodulation distortion term resulting from the multiplication.

The foregoing description has been presented for purposes of illustration and description. It is not exhaustive and does not limit embodiments to the precise forms disclosed. Modifications and variations are possible in light of the above teachings or may be acquired from the practicing embodiments consistent with those described herein. For example, some embodiments described herein only show two predistortion circuits, digital to analog converters, filters, and/or mixers, but in other instances different numbers of predistortion circuits, digital to analog converters, filters, and/or mixers may be used. For example, in some instances, three, four, five, or more digital predistortion circuits may be coupled in parallel to a digital input signal source. Each of these digital predistortion circuits may be coupled to a respective digital to analog converter and the converted outputs of two or more or all of the digital predistortion circuits may be mixed or otherwise combined to generate a higher bandwidth input signal to the power amplifier.

We claim:

1. A predistortion device comprising:
a digital predistortion circuit introducing an inversely modeled gain and phase characteristic of a radio power amplifier amplifying signals at a predetermined bandwidth into a digital input signal at a lower bandwidth than the predetermined bandwidth;
an digital to analog converter coupled to the digital predistortion circuit; and
a nonlinear analog circuit coupled to the digital to analog converter and nonlinearly expanding an analog converted output of the digital predistortion circuit from the lower bandwidth to the predetermined bandwidth.

2. The predistortion device of claim 1, further comprising:
a low pass filter coupled between the digital to analog converter and the nonlinear analog circuit; and
the radio power amplifier, wherein the radio power amplifier is coupled to an output of the nonlinear analog circuit and amplifies the predetermined bandwidth expanded analog converted output of the digital predistortion circuit.

3. The predistortion device of claim 1, wherein the digital predistortion circuit introduces a linear and third order intermodulation distortion term into the digital input signal and the nonlinear analog circuit nonlinearly expands the analog converted output of the digital predistortion circuit to a higher order intermodulation distortion term than the introduced third order term and includes a frequency translation mixer.

4. The predistortion device of claim 1, wherein the digital predistortion circuit introduces a second order intermodulation distortion term into the digital input signal and the nonlinear analog circuit nonlinearly expands the analog converted output of the digital predistortion circuit to a higher order intermodulation distortion term than the introduced second order term.

5. A predistortion device comprising:
a plurality of digital predistortion circuits coupled in a parallel to a source of digital input signal, each introducing an inversely modeled gain and phase characteristic of a radio power amplifier amplifying signals at a predetermined bandwidth into the digital input signal at a lower bandwidth than the predetermined bandwidth;
a plurality of digital to analog converters, each coupled to a respective digital predistortion circuit; and
an analog mixer coupled to each of the digital to analog converters for mixing analog converted outputs of each of the lower bandwidth digital predistortion circuits, wherein each of the lower bandwidths are selected to generate the predetermined bandwidth when mixed at the analog mixer.

6. The predistortion device of claim 5, wherein the analog mixer is an analog multiplier that multiplies the analog converted outputs of each of the lower bandwidth digital predistortion circuits together.

7. The predistortion device of claim 6, wherein:
the plurality of digital predistortion circuits includes a first predistortion circuit introducing a linear and third order intermodulation distortion term into the digital input signal and a second predistortion circuit introducing a second order intermodulation distortion term into the digital input signal; and
the analog mixer multiplies the analog converted outputs of the first and the second predistortion circuits and generates from the multiplication a power amplifier input signal including a fifth order intermodulation distortion term.

8. The predistortion device of claim 7, further comprising:
a first digital to analog converter coupled to the first predistortion circuit and the analog mixer;
a second digital to analog converter coupled to the second predistortion circuit and the analog mixer; and
the radio power amplifier.

9. The predistortion device of claim 8, further comprising:
a digital multiplier coupled to the first and the second predistortion circuits and multiplying an output of the first predistortion circuit by an output of the second predistortion circuit;
a nonlinear least squares solver coupled to the first and the second predistortion circuits, the digital multiplier, and an output of the power amplifier, the nonlinear least square solver (i) performing nonlinear least squares analysis of a digital multiplier output and the power amplifier output, (ii) calculating coefficient vectors of the second order and the third order intermodulation distortion terms from the nonlinear least squares analysis, and (iii) providing the first and the second predistortion circuits with filter coefficient updates from the calculated coefficient vectors.

10. The predistortion device of claim 9, wherein the nonlinear least squares solver evaluates the digital multiplier output as a function of a product of the second order and the third order intermodulation distortion terms and performs the nonlinear least squares analysis using a least squares algorithm.

11. The predistortion device of claim 8, further comprising a first and a second low pass filter coupled between the respective first and second digital to analog converters and the analog mixer.

12. The predistortion device of claim 5, further comprising a plurality of low pass filters, each coupled between a respective predistortion circuit and a respective digital to analog converter, wherein the inverse modeling at each of the respective predistortion circuits is band limited based on a respective low pass filter setting.

13. The predistortion device of claim 8, further comprising:
an inverse power amplifier modeling circuit coupled to an input and an output of the power amplifier, the inverse power amplifier modeling circuit inversely modeling the gain and phase characteristic of the radio power amplifier, comparing the inversely modeled gain and phase characteristic to signals at the input and the output of the power amplifier, and generating filter coefficient updates for at least one of the digital predistortion circuits that are sent to the at least one digital predistortion circuit.

14. A predistortion device comprising:
a plurality of digital predistortion circuits coupled in a parallel to a source of digital input signal, each introducing an inversely modeled gain and phase characteristic of a radio power amplifier amplifying signals at a predetermined bandwidth into the digital input signal at a lower bandwidth than the predetermined bandwidth;
a plurality of digital to analog converters, each coupled to a respective digital predistortion circuit;
a plurality of analog mixers, each coupled to a respective digital to analog converter and an oscillating signal selected to generate a signal having a higher bandwidth than a respective one of the lower bandwidths when mixed with a signal at the respective lower bandwidth outputted at the respective digital to analog converter; and
a multiplier multiplying each of the higher bandwidth signals outputted by each of the analog mixers.

15. The predistortion device of claim 14, further comprising a plurality of low pass filters, each coupled between each respective digital to analog converter and each respective analog mixer.

16. The predistortion device of claim 14, wherein the each of the higher bandwidth signals is at the predetermined bandwidth and the multiplier is part of a radio power amplifier and modulates a power supply of the radio power amplifier to multiply the higher bandwidth signals.

17. The predistortion device of claim 14, wherein each of the higher bandwidth signals is less than the predetermined bandwidth and the multiplier is a real multiplier and the output of the real multiplier is at the predetermined bandwidth in a radio frequency domain.

18. A method comprising:
identifying a bandwidth of an input to a radio power amplifier;
inversely modeling digital gain and phase characteristics of the radio power amplifier at a plurality of lower bandwidths than the identified bandwidth;
separately applying the inversely modeled digital gain and phase characteristics at each of the lower bandwidths to a digital input signal;
converting the separately applied modeled gain and phase characteristics to respective analog signals; and
mixing each of the converted lower bandwidth signals together to form a mixed signal having the identified bandwidth.

19. The method of claim 18, wherein:
the digital gain and phase characteristics are inversely modeled at two different lower bandwidths, a first bandwidth introducing a linear and a third order intermodulation distortion term into the digital input signal and a second bandwidth introducing a second order intermodulation distortion term into the digital input signal;
the converted linear and third order intermodulation distortion terms are multiplied by the converted second order intermodulation distortion terms to mix the first and the second bandwidth signals together; and
the mixed signal includes a fifth order intermodulation distortion term resulting from the multiplying.

20. A method comprising:
identifying a bandwidth of an input to a radio power amplifier;
applying an inversely modeled digital gain and phase characteristics of the radio power amplifier at a lower bandwidth than the identified bandwidth to a digital signal;
converting the applied modeled digital characteristics to an analog signal; and
applying a nonlinear function to the analog signal, the nonlinear function expanding the analog signal from the lower bandwidth to the identified bandwidth.
